(19) United States
(12) Patent Application Publication
(10) Pub. No.: US 2012/0113213 A1
(43) Pub. Date: May 10, 2012

(54) Wide format sensor

(75) Inventors: Anton Petrus Maria Van Arendonk, Waterloo (CA); Cornelis Draijer, Waterloo (CA)

(73) Assignee: Teledyne Dalsa, Inc.

(21) Appl. No.: 13/373,120

(22) Filed: Nov. 4, 2011

Related U.S. Application Data
(60) Provisional application No. 61/456,352, filed on Nov. 5, 2010.
(60) Provisional application No. 61/456,351, filed on Nov. 5, 2010.

(51) Int. Cl. H04N 5/335; H05K 3/00

(52) U.S. Cl. 348/36; 29/829; 348/E05.091

(57) ABSTRACT

A method of making a high resolution wide format sensor for imaging a moving image conjugate includes assembling, imaging and processing. Plural sensors are assembled on a carrier. Each sensor images a strip portion of the moving image conjugate. The plural sensors are disposed so that strip portions imaged by adjacent sensors overlap in a seam leaving no gaps between strip portions. The carrier and the sensors have been fabricated out of materials with compatible coefficients of thermal expansion. A known pattern is imaged to produce from the sensors corresponding plural strip image data. The strip image data are processed to determine offset and rotation parameters for each sensor by exploiting overlapping seams.

The priority of the Nov. 5, 2010 filing date of provisional application number 61/456,352 is hereby claimed and the priority of the Nov. 5, 2010 filing date of provisional application number 61/456,351 is hereby claimed.

### BACKGROUND OF THE INVENTION

In the machine vision technologies, inspection of articles moving on a conveyor belt typically uses a scanning type camera. The camera includes a lens, or more likely a lens system, to focus an image conjugate of the articles on the plane of a sensor in the camera. As the real article moves in the direction of the conveyor belt, the image conjugate moves in an opposite direction, but in the plane of the sensor in the camera.

A number of sensor technologies have developed for such scanning type cameras. Among them are line scan sensors and TDI sensors (time delay and integrate sensors), both of which capture the moving image in a kind of “push broom” scan.

More generally, applications of scanning type cameras vary from the factory conveyor belt to aerial photography. In aerial photography, the scanning type camera is mounted in a moving aircraft while the object being imaged lies motionless on the ground. There are many other applications for such a scanning type camera.

However, a limitation on a sensor for a scanning type camera is the tradeoff between resolution and sensor format size. If, for example, a sensor has an imaging width of 4096 pixels and the pixels are arrayed on 4 micron centers. The active sensor area would be required to have a width of more than 1.6 centimeters or about two-thirds of an inch. More pixels could be designed into the 1.6 centimeter width, but the pixels would be smaller and the resulting pixel sensitivity to light would be reduced. More 4 micron pixels could be arrayed in a sensor with a larger active area width, but the larger the sensor, the lower will be the yield. Significantly larger sensors encounter manufacturing problems that become worse as the width increases. As long as the article being imaged requires a resolution of less than one part in 4000, the above described sensor is would function fine. However, if the required resolution were to be, for example, one part in 32,000, a much more expensive sensor would be required. What is needed is a high resolution, large format sensor.

### SUMMARY OF THE INVENTION

In an embodiment, a method of making a high resolution wide format sensor for imaging a moving image conjugate includes assembling, imaging and processing. Plural sensors are assembled on a carrier. Each sensor images a strip portion of the moving image conjugate. The plural sensors are disposed so that strip portions imaged by adjacent sensors overlap in a seam leaving no gaps between strip portions. The carrier and the sensors have been fabricated out of materials with compatible coefficients of thermal expansion. A known pattern is imaged to produce from the sensors corresponding plural strip image data. The strip image data are processed to determine offset and rotation parameters for each sensor by exploiting overlapping seams.

### BRIEF DESCRIPTION OF DRAWINGS

The invention will be described in detail in the following description of preferred embodiments with reference to the following figures.

FIG. 1 is a schematic diagram depicting the relationship of overlapping sensors.

FIG. 2 is a schematic diagram depicting the extraction of offset and rotation parameters and/or the reconstruction of an image from extracted parameters.

### DETAILED DESCRIPTION OF PREFERRED EMBODIMENTS

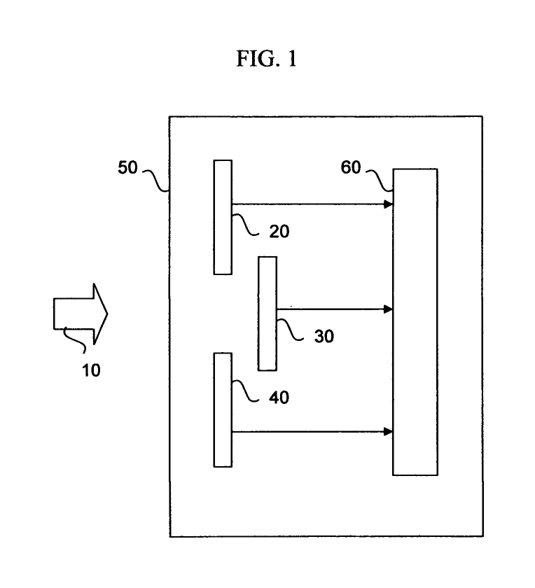

In accordance with embodiments of the present invention, a high resolution, large format sensor for a scanning type camera is fabricated from multiple smaller sensors. In FIG. 1, an image conjugate 10 is moved across three sensors 20, 30, 40. These sensor may be either line scan or TDI sensors. These sensors are positioned on carrier 50 so that image conjugate 10 is fully covered by the active areas of the sensors as the image conjugate moves across the sensor. The output from each of the sensors is provided to processor 60 which may be mounted on carrier 50 or separate from carrier 50. The separate images from the three sensors are combined in processor 60.

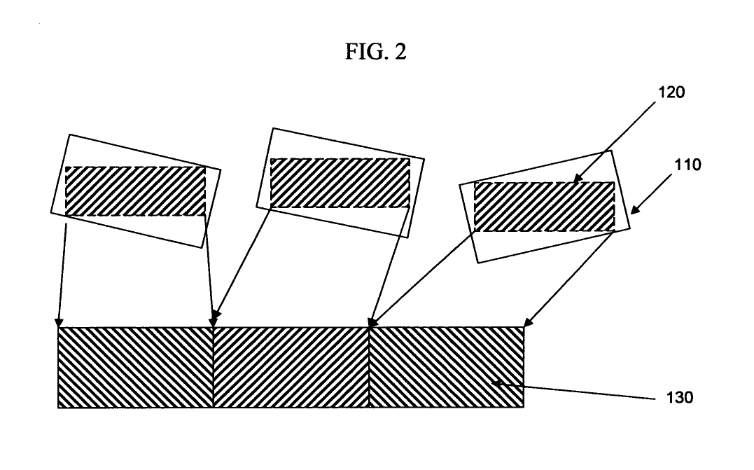

During manufacturing, sensors 20, 30 and 40 may be mounted on carrier 50 with displacement and/or rotational errors. Manufacturing tolerances make such errors almost inevitable. Processor 60 corrects for these errors. In FIG. 2, a sensor is mounted with rotational and displacement errors so that the active area is depicted at 110. Processor 60 extracts a corrected area 120 out of a sensor's active area 110. The extracted area 120 is stored within the processor's memory at location 130. Image data from each sensor is corrected in this way. A stitching algorithm smoothes the seam between adjacent sensor image data. In this way, the output of processor 60 appears to be from a much wider format sensor with greater resolution. Clearly, two or more sensors may be stitched together in this way to provide the function of a much wider sensor.

Large format sensors are expensive due to low manufacturing yield. This technique allows for the same functionality but with less expensive sensors. There is no need to try to butt one sensor exactly adjacent to another. This function is achieved in processor 60. Furthermore, if one of the sensors should later fail or be detected to have a defect, it is possible to replace a single sensor out of the plural sensors at a minimum cost.

Most sensors are based on silicon technology. When silicon based sensors are used, a silicon carrier is recommended to match the coefficient of thermal expansion. At least the carrier should have a similar coefficient of thermal expansion to that of the sensor, whatever the sensor is made of.

When a silicon based carrier 50 is used with silicon based sensors, the carrier by itself can have active semiconductor regions. For example, processor 60 might be implemented in the carrier 50. Other functions implemented on the carrier might include correlated double sampling, multiplexing or other techniques because the carrier is fully compatible with IC manufacturing processes. Furthermore, silicon carriers can mount surface mounted devices, components and flat cable attachments.

Processor 60 can only correct the displacement and rotational errors in the location of sensors if the processor knows precisely where the sensors are. This is achieved at the end of the assembly process. Once the carrier module is assembled, the sensors are used to scan a known calibration pattern. The processor examines the image data produced by the sensors from the image conjugate of the known calibration pattern. From this calibration process, the exact location and orientation of each sensor is determined. These calibration parameters are stored in a non-volatile memory. Then, when the carrier module is used during normal image scanning, the processor uses the calibration parameters to correct displacement and rotational errors in the sensor image data. The processor then stitches together all seams to provide a wide format, high resolution image.

In an alternative embodiment, carrier 50 is a base carrier fabricated from Covar™ or similar material with a coefficient of thermal expansions matched at nearly as possible to the silicon based sensors 20, 30, 40. The sensors are spaced as depicted in FIG. 1 so that it is easy to replace a non-functioning sensor and rescan a test pattern to calibrate the sensor system. Manufacturing tolerances for positioning the sensors are relaxed because the exact final positions are determined by calibration and the image data from the several sensor are stitched together.

Interconnecting wires between sensors, components, flat cable attachments, etc. are provided in the spaces between individual sensors. Multi-layer interconnect traces can be formed as thin or thick film structures directly on the base carrier. The image sensors may be attached by epoxy glue to the base carrier and connected by known wire bonding to the interconnect traces.

Having described preferred embodiments of a novel wide format sensor (which are intended to be illustrative and not limiting), it is noted that modifications and variations can be made by persons skilled in the art in light of the above teachings. It is therefore to be understood that changes may be made in the particular embodiments of the invention disclosed which are within the scope of the invention as defined by the appended claims.

Having thus described the invention with the details and particularity required by the patent laws, what is claimed and desired protected by Letters Patent is set forth in the appended claims.

What is claimed is:

1. A method of making a high resolution wide format sensor for imaging a moving image conjugate comprising:
assembling on a carrier a plurality of sensors, each sensor imaging a strip portion of the moving image conjugate, the plurality of sensors being so disposed that strip portions imaged by adjacent sensors overlap in a seam leaving no gaps between strip portions, the carrier and the sensors having been fabricated out of materials with compatible coefficients of thermal expansion;
imaging a predetermined known pattern to produce from the plurality of sensors a corresponding plurality of strip image data, and
processing the plurality of strip image data to determine offset and rotation parameters for each sensor by exploiting overlapping seams.

2. A method of using a high resolution wide format sensor for imaging a moving image conjugate, the wide format sensor comprising a plurality of sensors assembled on a carrier, each sensor for imaging a strip portion of the moving image conjugate, the plurality of sensors being so disposed that strip portions imaged by adjacent sensors overlap in a seam leaving no gaps between strip portions, the carrier and the sensors having been fabricated out of materials with compatible coefficients of thermal expansion, the method of using comprising:
imaging an unknown object to produce from the plurality of sensors a corresponding plurality of overlapping strip image data, and
processing the plurality of overlapping strip image data based on predetermined offset and rotation parameters to extract non-overlapping strip image data for each sensor.
